(19) United States
(12) Patent Application Publication
(10) Pub. No.: US 2019/0271083 A1
(43) Pub. Date: Sep. 5, 2019

(54) FILM FORMATION APPARATUS

(71) Applicant: TOSHIBA ELECTRONIC DEVICES & STORAGE CORPORATION, Tokyo (JP)

(72) Inventors: Yasuhiro ISOBE, Kanazawa Ishikawa (JP); Naoharu SUGIYAMA, Yokohama Kanagawa (JP); Takayuki SAKAI, Chofu Tokyo (JP); Masaaki ONOMURA, Setagaya Tokyo (JP)

(73) Assignee: TOSHIBA ELECTRONIC DEVICES & STORAGE CORPORATION, Tokyo (JP)

(21) Appl. No.: 16/125,368

(22) Filed: Sep. 7, 2018

(30) Foreign Application Priority Data
Mar. 2, 2018 (JP) 2018-037658

(51) Int. Cl. C23C 16/455; C23C 16/34; C23C 16/509

(52) U.S. Cl. CPC C23C 16/45591; C23C 16/509; C23C 16/34

(57) ABSTRACT

According to one embodiment, a film formation apparatus includes a substrate support member, a first gas supplier disposed above the substrate support member and supplying a first gas, a second gas supplier disposed between the substrate support member and the first gas supplier and supplying a second gas, and a plate member disposed between the first gas supplier and the second gas supplier and having a hole, the plate member defining a plasma generation area between the first gas supplier and the plate member, the plasma generation area generating plasma of the first gas, wherein the hole has a diameter between 0.1 to 2 mm and a depth between 0.1 to 5 mm.

### CROSS-REFERENCE TO RELATED APPLICATIONS

This application is based upon and claims the benefit of priority from Japanese Patent Application No. 2018-37658, filed Mar. 2, 2018, the entire contents of which are incorporated herein by reference.

### FIELD

Embodiments described herein relate generally to a film formation apparatus.

### BACKGROUND

Metal organic chemical vapor deposition (MOCVD) is widely known as a film formation method of a group III nitride semiconductor layer such as gallium nitride (GaN).

In the process of forming the group ITT nitride semiconductor layer using plasma enhanced MOCVD for low cost fabrication, a plate member with a plurality of holes disposed between a first gas supplier supplying a first gas containing nitrogen gas and a second gas supplier supplying a second gas containing a metal organic gas is proposed.

However, the structure of plate member in the film formation apparatus can still be further optimized.

### BRIEF DESCRIPTION OF THE DRAWINGS

FIG. 1 is a schematic view of the structure of a film formation apparatus of a first embodiment.

FIG. 2 is a plan view of the structure of a plate member of the first embodiment.

FIG. 3 is a cross-sectional view of the structure of a hole in the plate member of the first embodiment.

FIG. 4 shows plasma light emission spectrum immediately above a substrate in relation to the first embodiment.

FIG. 5 shows whether or not electric discharge occurs immediately above the substrate where a diameter and a depth of the hole are changed in relation to the first embodiment.

FIG. 6 is a cross-sectional view of the structure of a hole in a plate member in relation to a variation of the first embodiment.

FIG. 7 is a plan view showing the structure of a hole in a plate member of a second embodiment.

### DETAILED DESCRIPTION

In general, according to one embodiment, a film formation apparatus includes: a substrate support member; a first gas supplier disposed above the substrate support member and supplying a first gas; a second gas supplier disposed between the substrate support member and the first gas supplier and supplying a second gas; and a plate member disposed between the first gas supplier and the second gas supplier and having a hole, the plate member defining a plasma generation area between the first gas supplier and the plate member, the plasma generation area generating plasma of the first gas, wherein the hole has a diameter between 0.1 to 2 mm and a depth between 0.1 to 5 mm.

Hereinafter, embodiments will be explained with reference to accompanying drawings.

### Embodiment 1

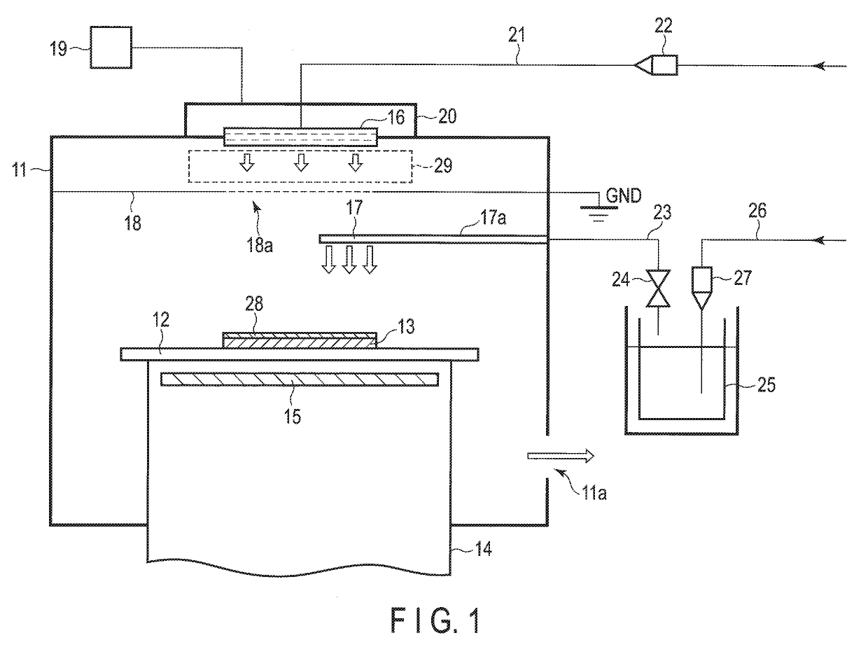

FIG. 1 shows the structure of a film formation apparatus of a first embodiment. Specifically, FIG. 1 shows the structure of a metal organic chemical vapor deposition (MOCVD) with plasma source apparatus.

A susceptor (substrate support member) 12 is disposed in a chamber 11 including a discharge port 11a, and a substrate (for example, semiconductor wafer) 13 is disposed on the susceptor 12. The susceptor 12 is rotatable with a rotation mechanism 14. Furthermore, a heater 15 is provided below the susceptor 12 to heat the substrate 13 to a desired temperature.

A first gas supplier 16 configured to supply a first gas (which will be described later) is disposed above the susceptor 12. Specifically, the first gas supplier 16 is a shower head nozzle. A second gas supplier 17 configured to supply a second gas (which will be described later) is disposed between the susceptor 12 and the first gas supplier 16. Specifically, a gas outlet port part of a gas introduction nozzle 17a which introduces the second gas into the chamber 11 corresponds to the second gas supplier 17. A plate member 18 with a hole 18a is disposed between the first gas supplier 16 and the second gas supplier 17. The plate member 18 will be described later.

The first gas supplier (shower head nozzle) 16 is used as an electrode to supply RF power. That is, RF power is supplied to the first gas supplier 16 from an RF power source (high frequency power source of approximately 60 MHz) 19 via a matching box 20.

Furthermore, a gas supply tube 21 is connected to the first gas supplier (shower head nozzle) 16, and a desired gas is supplied to the first gas supplier (shower head nozzle) 16 from the gas supply tube 21 via a mass-flow controller 22.

A gas supply tube 23 is connected to the gas introduction nozzle 17a, and a material supply part 25 is connected to the gas supply tube 23 via a needle valve (or automatic pressure controller) 24. A material of the second gas is stored in the material supply part 25. A gas for bubbling is supplied to the material supply part 25 from the gas supply tube 26 via a mass-flow controller 27, and vaporized gas by bubbling is supplied into the chamber 11.

The film formation apparatus of the present embodiment can form a group III nitride semiconductor layer 28 on the substrate 13.

In that case, the first gas contains nitrogen gas (N₂ gas). Specifically, the first gas contains nitrogen gas (N₂ gas) and hydrogen gas (H₂ gas).

Furthermore, the second gas contains a metal organic gas containing a group III metal element. The group III metal element may be gallium (Ga), aluminum (Al), or indium (In), for example. To form gallium nitride (GaN), trimethylgallium is used as a metal organic gas. To form aluminum nitride (AlN), trimethylaluminum is used as a metal organic gas. To form indium nitride (InN), trimethylindium is used as a metal organic gas.

When the first gas is supplied from the first gas supplier to the chamber 11 and RF power is supplied from the RF power source 19 to the first gas supplier, plasma is generated in an area between the first gas suppler 16 and the plate member 18. That is, the area between the first gas supplier 16 and the plate member 18 is a plasma generation area 29 where the first gas becomes plasma. When the first gas becomes plasma in the plasma generation area 29, nitrogen radical (N radical) is generated. The nitrogen radical passes through a plurality of holes 18a of the plate member 18 to be supplied onto the surface of the substrate 13. On the other hand, the second gas containing the metal organic gas is supplied to the surface of the substrate 13 from the second gas supplier 17. As a result, the nitrogen radical and the metal organic gas react, and a group III nitride semiconductor layer 28 is formed on the substrate.

To produce a group III nitride semiconductor layer 28 of good quality, keeping plasma in the plasma generation area 29 is important. That is, preventing plasma generated in the plasma generation area 29 from leaking outside the plate member 18 through the holes 18a is important.

In order to keep the plasma in the plasma generation area 29, a diameter of the hole 18a, depth of the hole 18a (thickness of the plate member 18) are important. In the following description, the plate member 18 with the holes 13a will be described.

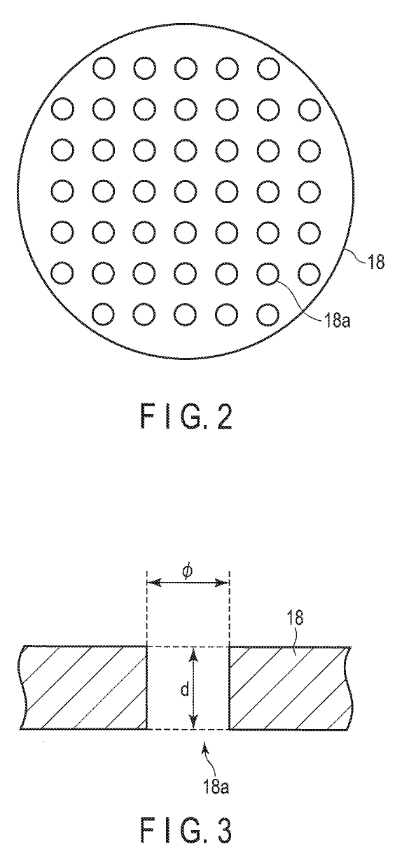

FIG. 2 is a plan view of the structure of the plate member 18. As shown in FIG. 2, the plate member 18 includes a plurality of circular holes 18a provided in a mesh-like fashion.

FIG. 3 is a cross-sectional view of the structure of the hole 18a. As shown in FIG. 3, the hole 18a has a diameter of φ, and a depth (thickness of plate member 18) d.

The plate member 18 is, preferably, formed of a metal or a metal coated with an insulative substance. Furthermore, the plate member 18 is, preferably, grounded.

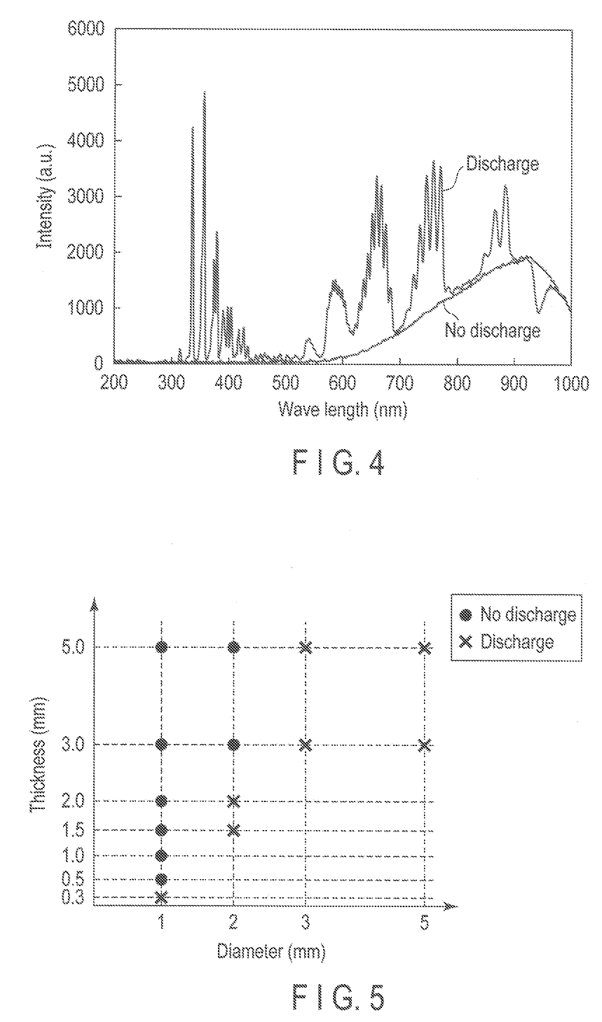

FIG. 4 shows plasma light emission spectrum detected immediately above the substrate 13. By adjusting the diameter φ and the depth d of the hole 18a, electric discharge immediately above the substrate 13 can be prevented.

FIG. 5 shows a simulation result of whether or not the electric discharge occurs immediately above the substrate 13 where the diameter φ and the depth d of the hole 18a are changed. In this simulation, RF power=4 kW, RF frequency=60 MHz and pressure=100 Pa, in N₂ atmosphere.

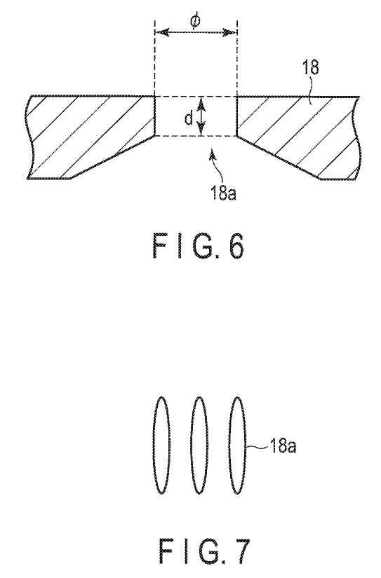

As shown in FIG. 5, whether or not the discharge occurs depends on the diameter φ of the hole 18a, depth d of the hole 18a, and aspect ratio (ratio of depth d to diameter φ, that is, d/φ) of the hole 18a. A result of the simulation of FIG. 5 indicates that electric discharge does not occur immediately above the substrate 13 where the diameter φ of the hole 18a 1 mm and the depth d of the hole 18a is between 0.5 and 5.0 mm. Furthermore, the discharge does not occur where the diameter α of the hole 18a is 2 mm and the depth d of the hole 18a is between 3.0 to 5.0 mm. Furthermore, the result of the simulation of FIG. 6 indicates that the aspect ratio (d/φ) of the hole 18a is a factor to determine whether or not the discharge occurs. Furthermore, although the simulation of FIG. 5 is performed where RF power=4 kW and pressure=100 Pa, the film formation is, in general, performed where the RF power supplied to the film formation apparatus is between 1 and 5 kW and the pressure in the chamber is between 10 and 1000 Pa (or more generally, between 50 and 400 Pa). Therefore, suitable ranges of the above factors will be: the diameter of the hole 18a is between 0.1 and 2 mm, the depth of the hole 18a Is between 0.1 and 5 mm, and the ratio of the depth to the diameter (aspect ratio) is between 0.5 and 2.0.

As can be understood from the above, in the present embodiment, the plate member 18 with holes 18a is interposed between the first gas supplier and the second gas supplier and the diameter φ, depth d and aspect ratio (d/φ) of the hole 18a are optimized to prevent leaking of the plasma generated in the plasma generation area 29 to the outside of the plate member 18 through the holes 18a. Therefore, a good quality layer of group III nitride semiconductor layer or the like can be formed on the substrate 13 without exposing the layer to the plasma.

FIG. 6 shows the structure of a variation of the present embodiment. Specifically, it is a cross-sectional view of a hole 18a in a plate member 18. In this variation, the lower part of the plate member 18 (the side opposite to the plasma generation area 29 side) is tapered. If the thickness of the plate member 18 is great, a substantial depth of a hole (depth in the non-tapered part d) can be properly adjusted with the tapered part.

### Embodiment 2

Now, a film formation apparatus of the second embodiment will be explained. Note that structural elements of the second embodiment are the same as those of the first embodiment, and thus, description considered redundant will be omitted.

FIG. 7 is a plan view of the structure of a hole 18a in a plate member 18 in a film formation apparatus of the second embodiment. Note that the structure of the film formation apparatus is similar to that of FIG. 1.

As shown in FIG. 7, in the present embodiment, a slit-shaped holes 18a are formed in the plate member 18. Specifically, the plate member 18 includes slit-shaped and elliptical holes 18a. The basic cross-sectional shape of the hole 18a is similar to that of the first embodiment. In that case, a short diameter of the ellipse in the short axis direction is, preferably, set to φ such that the conditions of the hole 18a of the first embodiment can be satisfied.

With the slit -shaped holes 18a in the plate member 18, leaking of the plasma generated in the plasma generation area 29 to the outside of the plate member 18 through the holes 18a can he prevented. Therefore, as in the first embodiment, a good quality layer of group III nitride semiconductor layer or the like can be formed on the substrate 13 without exposing the layer to the plasma.

Furthermore, with the slit-shaped holes 18a, the aperture ratio can be increased as compared to a case where the circular holes are provided, and thus, the efficiency of film formation can be increased.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A film formation apparatus comprising:
a substrate support member;
a first gas supplier disposed above the substrate support member and supplying a first gas;
a second gas supplier disposed between the substrate support member and the first gas supplier and supplying a second gas; and
a plate member disposed between the first gas supplier and the second gas supplier and having a hole, the plate member defining a plasma generation area between the first gas supplier and the plate member, the plasma generation area generating plasma of the first gas, wherein
the hole has a diameter between 0.1 to 2 mm and a depth between 0.1 to 5 mm.

2. The apparatus of claim 1, wherein a ratio of the depth of the hole to the diameter of the hole is between 0.5 and 2.0.

3. The apparatus of claim 1, wherein the first gas contains a nitrogen gas.

4. The apparatus of claim 1, wherein the second gas contains a metal organic gas including a group III metal element.

5. The apparatus of claim 1, wherein the plate member is formed of a metal member or a metal member coated with an insulative substance.

6. The apparatus of claim 1, wherein
the first gas contains a nitrogen gas,
the second gas contains a metal organic gas containing a group III metal element, and
a group III nitride semiconductor layer is formed on a substrate supported by the substrate support member with nitrogen radical generated by the plasma of the first gas and the second gas.

7. The apparatus of claim 1, wherein a pressure in a chamber in which the group III nitride semiconductor layer is formed is between 10 and 1000 Pa.

8. The apparatus of claim 1, wherein power supplied to the film formation apparatus is between 1 and 5 kW.

9. A film formation apparatus comprising:
a substrate support member;
a first gas supplier disposed above the substrate support member and supplying a first gas;
a second gas supplier disposed between the substrate support member and the first gas supplier and supplying a second gas; and
a plate member disposed between the first gas supplier and the second gas supplier and having a hole, the plate member defining a plasma generation area between the first gas supplier and the plate member, the plasma generation area generating plasma of the first gas, wherein
the hole is a slit.

10. The apparatus of claim wherein the first gas contains a nitrogen gas.

11. The apparatus of claim 9, wherein the second gas contains a metal organic gas containing a group III metal element.

12. The apparatus of claim 9, wherein the plate member is formed of a metal member or a metal member coated with an insulative substance.

13. The apparatus of claim 9, wherein
the first gas contains a nitrogen gas,
the second gas contains a metal organic gas containing a group III metal element, and
a group III nitride semiconductor layer is formed on a substrate supported by the substrate support member with nitrogen radical generated by the plasma of the first gas and the second gas.

14. The apparatus of claim 9, wherein a pressure in a chamber in which the group III nitride semiconductor layer is formed is between 10 and 1000 Pa.

15. The apparatus of claim 9, wherein power supplied to the film formation apparatus is between 1 and 5 kW.
